(19) United States
(12) Patent Application Publication
(10) Pub. No.: US 2006/0176667 A1
(43) Pub. Date: Aug. 10, 2006

(54) Device for controlling fan speed

(75) Inventor: Michael Chen, Taipei Hsien (TW)

Correspondence Address: BIRCH STEWART KOLASCH & BIRCH, PO BOX 747, FALLS CHURCH, VA, 22040-0747, US

(73) Assignee: TOPOWER COMPUTER INDUSTRIAL CO., LTD.

(21) Appl. No.: 11/049,743

(22) Filed: Feb. 4, 2005

(51) Int. Cl. H05K 7/20

(52) U.S. Cl. 361/695

(57) ABSTRACT

A device for controlling fan speed is disposed between a fan for dissipating heat of a heat source and a power supply for providing a fan with driving power. The device for controlling fan speed according to the present invention includes a rotation speed controlling unit and a switching unit, wherein according to a reference signal of the heat source, the rotation speed controlling unit controls the fan in a changeable rotation speed mode, the switching unit switches the fan to the changeable rotation speed mode or a fixed rotation speed mode, and according to the fixed rotation speed mode, the power supply directly provides the driving power to keep the rotation speed of the fan, whereby a user forces the fan to increase the rotation speed and then acquire a best performance of heat dissipating in accordance with the operating environment or the requirement of the heat source.

### FIELD OF THE INVENTION

The present invention relates to a device for controlling fan speed, and more particularly to a device for controlling fan speed capable of switching the fan to a fixed rotation speed mode or a changeable rotation speed mode, wherein a user can force the fan to be in the fixed rotation speed mode and the rotation speed of the changeable rotation speed mode automatically depends on a reference signal of the heat source.

### BACKGROUND OF THE INVENTION

According to the development of precision technology, the volume of an electronic device is gradually decreased, but the performance of the electronic device is requested to gradually increase. Thus, the heat dissipating problem of the electronic device is gradually serious. However, current improvement methods mainly utilize an air cooling type heat dissipating fan to guide air and then cool the electronic device. Moreover, the heat generated from the electronic device depends on various parameters of the work time and operation power, and thus a device of controlling fan speed disclosed in most reference patent documents or products receives a reference signal transmitted from the electronic device. The device of controlling fan speed changes the rotation speed of the heat dissipating fan in accordance with the reference signal, whereby different dissipating performance of the heat dissipating fan depends on different heat generated from the electronic device.

The rotation speed of the heat dissipating fan disclosed in current reference patent documents or products is passively controlled after the heat is generated from the electronic device. However, gradually this method for controlling the heat dissipating fan cannot meet the requirement of the electronic device in the future. For example, the electronic device is a power supply. When an external power source provides the electronic device with electric power and transforms the electric power to a load, the electronic device will provide the load with more power so as to increase the temperature of a heat source of the electronic device if the electric potential of the load is increased (e.g. the quantity of the load is increased). After the temperature is high, the rotation speed of the heat dissipating fan is increased for dissipating the heat. According to the electronic device, various electronic components of the electronic device all are heated and then cooled, and thus they are still expanded when hot and to shrunk when cold or they have high thermal impedance, whereby the performance and lifetime of the electronic device are decreased. In addition, various electronic devices disposed in a computer all generate the heat and the interior of the computer is similar to a closed space, thus the heat is quickly accumulated. When a user cannot force the heat dissipating fan to quickly dissipate the heat, possibly the user won't be able to start up the computer because the environmental temperature of the electronic device is too high so as to result in a fault command.

### SUMMARY OF THE INVENTION

It is an object of the present invention to solve the above-mentioned disadvantages. The present invention provides a device for controlling fan speed to switch the fan to a fixed rotation speed mode or a changeable rotation speed mode in accordance with the operating environment or the requirement of the heat source, wherein the user can force the fan to be in the fixed rotation speed mode and the rotation speed of the changeable rotation speed mode automatically depends on the reference signal of the heat source. The device for controlling fan speed according to the present invention includes a rotation speed controlling unit and a switching unit, wherein according to a reference signal of the heat source the rotation speed controlling unit controls the fan in a changeable rotation speed mode, the switching unit switches the fan to the changeable rotation speed mode or a fixed rotation speed mode, and according to the fixed rotation speed mode the power supply directly provides the driving power to keep the rotation speed of the fan, whereby the user forces the fan to increase the rotation speed and then acquire a best performance of heat dissipating in accordance with the operating environment or the requirement of the heat source.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic block diagram showing a circuit of the present invention.

FIG. 2 is a schematic block diagram showing a circuit in an embodiment of the present invention.

FIG. 3 is a perspective view showing a device for controlling fan speed of the prevent invention applied to a computer.

### DETAILED DESCRIPTION OF THE PREFERRED EMBODIMENTS

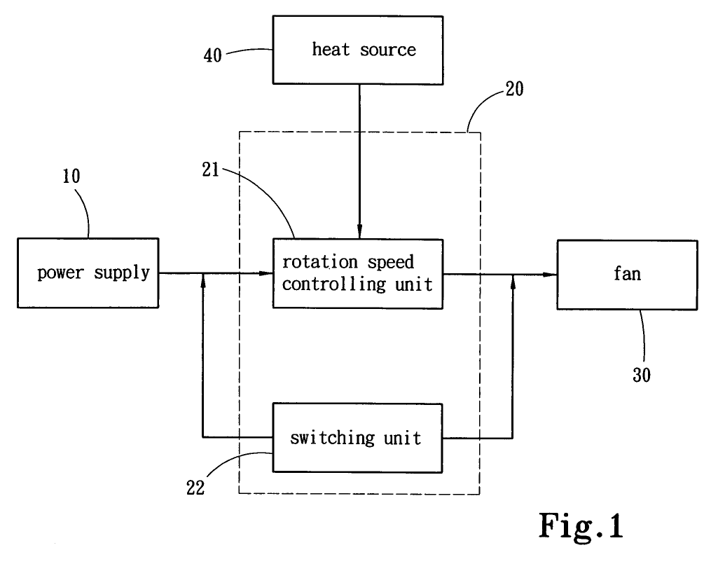

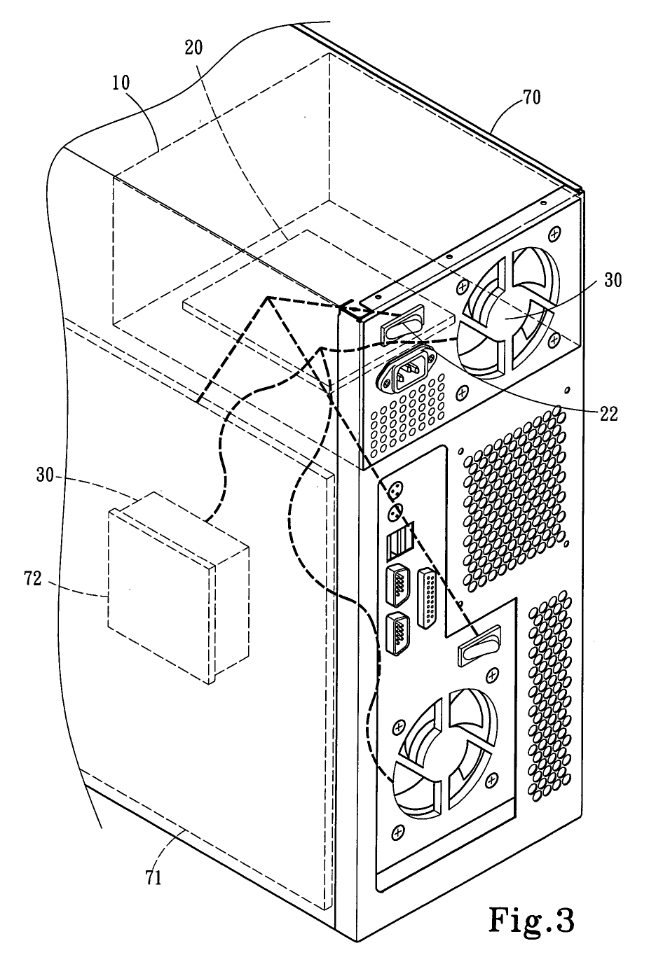

Referring to FIG. 1, it depicts a schematic block diagram showing a circuit of the present invention. As shown in FIG. 1, a device 20 for controlling fan speed according to the present invention can improve conventional device for controlling fan speed. The device 20 for controlling fan speed is disposed between a fan 30 and a power supply 10, wherein the fan 30 dissipates the heat of a heat source 40 and the power supply 10 provides the fan 30 with driving power. As shown in FIG. 3, the fan 30 can be an internal fan 30 disposed in the power supply 10, a heat dissipating fan 30 disposed on a central processor 72 or other fans 30 for dissipating the heat generated from other devices of a computer 70. The device 20 for controlling fan speed includes a rotation speed controlling unit 21 and a switching unit 22, wherein according to the reference signal of the heat source 40 the rotation speed controlling unit 21 can change the driving power and control the fan 30 in a changeable rotation speed mode, the switching unit 22 can switch the fan 30 to the changeable rotation speed mode or a fixed rotation speed mode, and according to the fixed rotation speed mode the power supply 10 directly provides the driving power to keep the rotation speed of the fan 30.

Referring to FIGS. 1 and 3 again, they are apparently that the switching unit 22 can be a switch, which is disposed on a casing surface of the power supply 10 or outside the casing of the computer 70, or the switching unit 22 can be an external auxiliary device (such as a computer mouse or keyboard) which is electrically connected to a mother board 71 by means of electric wire, thereby switching the fan 30 to the changeable rotation speed mode or the fixed rotation speed mode. When a user operates the switching unit 22 to be in an open loop manner according to the requirement of the heat source 40 or the judgment of environmental condition, the power supply 10 provides the rotation speed controlling unit 21 with the driving power. Simultaneously, according to a reference signal of the heat source 40, the rotation speed controlling unit 21 controls the driving power and the fan 30 to be in the changeable rotation speed mode. The reference signal of the heat source 40 can be a temperature sensor signal, an output signal of work time, or a signal of work power of the heat source 40. According to the variation of the reference signal, the rotation speed controlling unit 21 changes the driving power and achieve an objective of the control of rotation speed of the fan 30. If the user judges that the heat source 40 will quickly generate the heat (e.g. a plurality of electronic devices is multi-functionally run and thus the output power of the power supply 10 must be increased.), the user operates the switching unit 22 to be in a closed loop manner. Simultaneously, the power supply 10 will provide the driving power to pass through the switching unit 22. The electric potential of the driving power which is directly passed through the switching unit 22 is larger than the electric potential of driving power which is passed through the rotation speed controlling unit 21, and thus the rotation speed of the fan 30 will be increased according to the driving power which is directly passed through the switching unit 22, thereby being in fixed rotation speed mode. The fixed rotation speed of the fixed rotation speed mode is equal to a maximum rotation speed of the changeable rotation speed mode, such that the fan 30 has the best performance to dissipate the heat generated from the heat source 30.

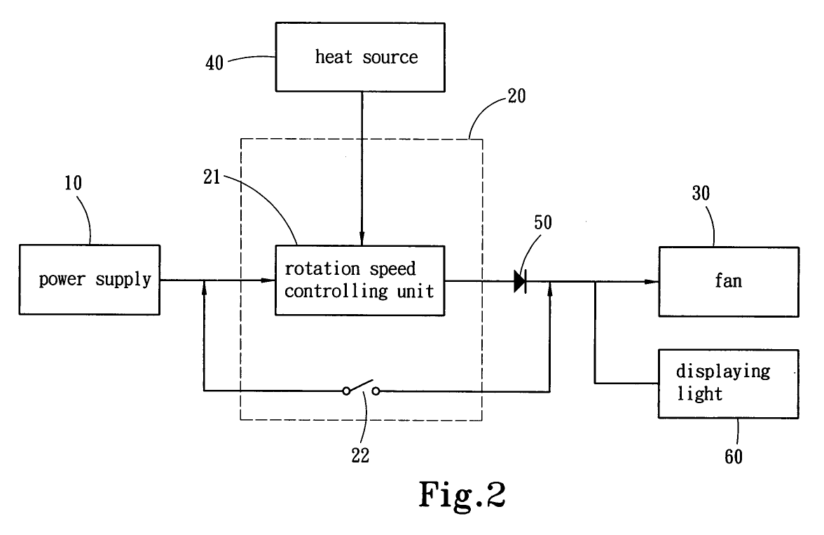

Referring to FIG. 2, the rotation speed controlling unit 21 of the present invention can include a protective element 50 such as a diode for preventing the driving power of the switching unit 22 from the interference, and thus the protective element 50 ensures that the fan 30 is kept in the fixed rotation speed mode. In addition, the principle of the device 20 of the present invention is not only applied to the fan 30 but also is applied to a displaying light 60 of the computer 70.

Although the invention has been explained in relation to its preferred embodiment, it is not used to restrain the invention. It is to be understood that many other possible modifications and variations can be made by those skilled in the art without departing from the spirit and scope of the invention as hereinafter claimed.

What is claimed is:

1. A device for controlling fan speed disposed between a fan for dissipating heat of a heat source and a power supply for providing a fan with driving power, which is characterized in:
the device for controlling fan speed including a rotation speed controlling unit and a switching unit, wherein according to a reference signal of the heat source the rotation speed controlling unit controls the fan in a changeable rotation speed mode, the switching unit switches the fan to the changeable rotation speed mode or a fixed rotation speed mode, and according to the fixed rotation speed mode, the power supply directly provides the driving power to keep the rotation speed of the fan.

2. The device for controlling fan speed according to claim 1, wherein the switching unit is a switch.

3. The device for controlling fan speed according to claim 1, wherein the reference signal is a temperature sensor signal.

4. The device for controlling fan speed according to claim 1, wherein the reference signal is an output signal of work time.

5. The device for controlling fan speed according to claim 1, wherein the reference signal is a signal of work power.

6. The device for controlling fan speed according to claim 1, wherein the fan has a fixed rotation speed of the fixed rotation speed mode being equal to a maximum rotation speed of the changeable rotation speed mode.

7. The device for controlling fan speed according to claim 1, wherein the rotation speed controlling unit includes a protective element for preventing the driving power of the switching unit from the interference.

8. The device for controlling fan speed according to claim 7, wherein the protective element is a diode.
